(19) United States
(12) Patent Application Publication
(10) Pub. No.: US 2026/0361282 A1
(43) Pub. Date: Nov. 12, 2026

(54) AMPLIFIER CIRCUIT AND MEMORY DEVICE INCLUDING THE SAME

(71) Applicant: Samsung Electronics Co., Ltd., Suwon-si (KR)

(72) Inventors: Sehwan Lee, Suwon-si (KR); Jung-June Park, Suwon-si (KR); Jungmin Seo, Suwon-si (KR); Byungkwan Chun, Suwon-si (KR)

(73) Assignee: Samsung Electronics Co., Ltd., Suwon-si (KR)

(21) Appl. No.: 19/543,649

(22) Filed: Feb. 18, 2026

(30) Foreign Application Priority Data
May 12, 2025 (KR) 10-2025-0061328

(51) Int. Cl. H03F 3/45; G11C 7/06

(52) U.S. Cl. CPC H03F 3/45179; G11C 7/062; H03F 2203/45028

(57) ABSTRACT

An amplifier circuit includes an input stage configured to receive an input signal and generate an internal current signal, a cascode stage connected to the input stage and configured to amplify the internal current signal transmitted from the input stage into an amplified signal through a cascode structure, and an output stage configured to output an output signal based on the amplified signal transmitted from the cascode stage, wherein the cascode stage includes a first cascode transistor having one end connected to the input stage and another end connected to a first node, and a second cascode transistor having one end connected to the input stage and another end connected to a second node, wherein the gate of the first cascode transistor is connected to the second node, and the gate of the second cascode transistor is connected to the first node.

### CROSS-REFERENCE TO RELATED APPLICATIONS

This present application claims priority to and the benefit under 35 U.S.C. § 119(a)-(d) of Korean Patent Application No. 10-2025-0061328, filed on May 12, 2025, in the Korean Intellectual Property Office, the entire disclosure of which is incorporated herein by reference.

### FIELD

The present disclosure relates to an amplifier circuit and a memory device including the same.

### BACKGROUND

A folded cascode amplifier is a structure widely used in semiconductor analog circuits, and is a structure that may realize high-gain characteristics by securing a high output impedance by arranging transistors of an input stage and an amplification stage with complementary polarities. However, due to the high input impedance formed in the amplification stage, a problem may arise in that the gain of the entire circuit is limited or the bandwidth characteristics are degraded. Accordingly, the technical demand for an amplifier circuit capable of improving gain and expanding bandwidth while maintaining structural efficiency is gradually increasing.

The information described above is for improving the understanding of the background of the present disclosure and may include information that does not constitute the related art.

### SUMMARY

In some embodiments, an amplifier circuit may include an input stage configured to receive an input signal and generate an internal current signal, a cascode stage connected to the input stage and configured to amplify the internal current signal transmitted from the input stage into an amplified signal through a cascode structure, and an output stage configured to output an output signal based on the amplified signal transmitted from the cascode stage, wherein the cascode stage may include a first cascode transistor having one end connected to the input stage and another end connected to a first node, and a second cascode transistor having one end connected to the input stage and another end connected to a second node, and wherein the gate of the first cascode transistor is connected to the second node, and the gate of the second cascode transistor is connected to the first node.

In some embodiments, a memory device may include a memory cell array, and a control logic circuit configured to control the memory cell array and may include an amplifier circuit configured to amplify an input signal received from an external device, wherein the amplifier circuit may include a first input transistor having one end connected to an input current source, another end connected to a first node, and a first input signal applied to a gate thereof, a second input transistor having one end connected to the input current source, another end connected to a second node, and a second input signal applied to a gate thereof, a first bias current source having one end connected to the first node and another end connected to a ground voltage, a second bias current source having one end connected to the second node and another end connected to the ground voltage, a first cascode transistor having one end connected to the first node and another end connected to a third node, a second cascode transistor having one end connected to the second node and another end connected to a fourth node, a first load element having one end connected to a power supply voltage and another end connected to the third node, and a second load element having one end connected to the power supply voltage and another end connected to the fourth node, and wherein the gate of the first cascode transistor is connected to the fourth node, and the gate of the second cascode transistor is connected to the third node.

In some embodiments, an amplifier circuit may include a first input transistor having one end connected to an input current source, another end connected to a first node, and a first input signal applied to a gate thereof, a second input transistor having one end connected to the input current source, another end connected to a second node, and a second input signal applied to a gate thereof, a first bias current source having one end connected to the first node and another end connected to a ground voltage, a second bias current source having one end connected to the second node and another end connected to the ground voltage, a first cascode transistor having one end connected to the first node and another end connected to a third node, a second cascode transistor having one end connected to the second node and another end connected to a fourth node, a first load element having one end connected to a power supply voltage and another end connected to the third node, and a second load element having one end connected to the power supply voltage and another end connected to the fourth node, wherein a first output signal is output through the third node, a second output signal is output through the fourth node, the gate of the first cascode transistor is directly connected to the fourth node, and the gate of the second cascode transistor is directly connected to the third node, the first input signal and the second input signal are a differential input signal pair, and the first output signal and the second output signal are a differential output signal pair.

According to various embodiments of the present disclosure, an amplifier circuit to which a cross-coupled structure is applied may be provided. As a result, the effective input impedance on the source side of the cascode transistor may be reduced, gain loss due to current division may be suppressed, and a wide output swing and stable frequency response characteristics may be secured even in a limited power supply voltage environment.

According to various embodiments of the present disclosure, the bandwidth characteristics may be improved by enhancing the current driving capability of the circuit along with the reduction of the impedance of the input node of the cascode stage included in the amplifier circuit. In particular, since stable gain characteristics may be secured even in a high-frequency region, the amplifier circuit according to the present disclosure may be advantageously applied even in application fields requiring high-speed operation.

According to various embodiments of the present disclosure, by applying a cross-coupled structure to the amplifier circuit, gain and bandwidth improvement may be achieved without additional complex auxiliary circuits. Through such a configuration, an advantage may also be provided in that the total area of the circuit may be effectively reduced or the performance per unit area may be maximized.

### BRIEF DESCRIPTION OF THE DRAWINGS

FIG. 1 is a block diagram for explaining an amplifier circuit according to some embodiments of the present disclosure.

FIG. 2 is a circuit diagram for explaining an amplifier circuit according to some embodiments of the present disclosure.

FIG. 3 is a diagram for explaining a small-signal model of the amplifier circuit illustrated in FIG. 2.

FIG. 4 is a circuit diagram for explaining an amplifier circuit according to some embodiments of the present disclosure.

FIG. 5 is a diagram for explaining a small-signal model of the amplifier circuit illustrated in FIG. 4.

FIG. 6 is a graph comparing the gain by frequency between the amplifier circuit illustrated in FIGS. 2 and 3 and the amplifier circuit illustrated in FIGS. 4 and 5.

FIGS. 7 to 16 are diagrams for explaining an amplifier circuit according to some embodiments of the present disclosure.

FIG. 17 is a block diagram for explaining a memory system according to some embodiments of the present disclosure.

FIG. 18 is a block diagram illustrating an example of an electronic device provided with an amplifier circuit according to some embodiments of the present disclosure.

### DETAILED DESCRIPTION

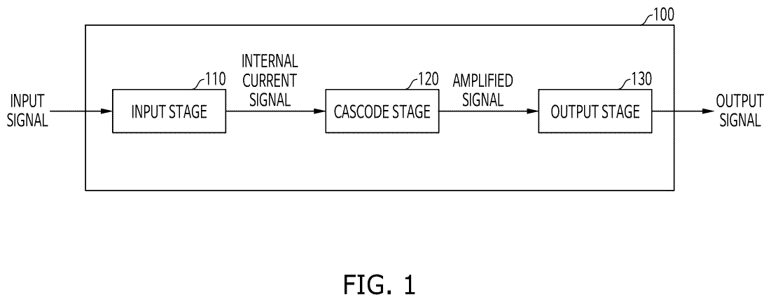

Hereinafter, various embodiments of the present disclosure will be described with reference to FIGS. 1 to 18. Throughout the specification, the same reference numerals may refer to the same constituent elements.

FIG. 1 is a block diagram for explaining an amplifier circuit according to some embodiments of the present disclosure.

Referring to FIG. 1, an amplifier circuit 100 may include an input stage 110, a cascode stage 120, and an output stage 130.

The amplifier circuit 100 may be implemented as a circuit that receives an INPUT SIGNAL, converts the INPUT SIGNAL into an INTERNAL CURRENT SIGNAL, generates an AMPLIFIED SIGNAL by amplifying the converted INTERNAL CURRENT SIGNAL through a cascode structure, and then provides an OUTPUT SIGNAL based on the AMPLIFIED SIGNAL. In FIG. 1, only the core components of the amplifier circuit 100 according to embodiments of the present disclosure are illustrated, and a person of ordinary skill in the art may understand that various additional circuits not illustrated in FIG. 1 may be added.

The input stage 110 may receive an INPUT SIGNAL from the outside and generate an INTERNAL CURRENT SIGNAL corresponding to the input signal. The INPUT SIGNAL may be in the form of a voltage or current, but is not limited thereto. In addition, the INPUT SIGNAL may be input from various electronic devices such as a sensor, a microcontroller, a control block of a memory circuit, etc., but is not limited to the above-mentioned examples. For example, when the amplifier circuit 100 is implemented in a memory device, the INPUT SIGNAL may be a signal transmitted from an external interface or an internal control logic circuit. According to embodiments of the present disclosure, the INPUT SIGNAL may be configured as a differential input signal pair, but is not limited thereto. The input stage 110 may generate the INTERNAL CURRENT SIGNAL according to characteristics such as the voltage magnitude, phase, waveform, and frequency of the INPUT SIGNAL, and the generated INTERNAL CURRENT SIGNAL may be transmitted to a subsequent stage, the cascode stage 120.

The cascode stage 120 may be configured to receive the INTERNAL CURRENT SIGNAL provided from the input stage 110 and amplify the INTERNAL CURRENT SIGNAL into an AMPLIFIED SIGNAL through a cascode structure. The cascode stage 120 may stably amplify the current signal transmitted from the input stage 110 in a higher output impedance environment.

In some embodiments, the cascode stage 120 may include a folded cascode structure that operates by separating current paths to different potential levels, but is not limited thereto.

In some embodiments, the cascode stage 120 may include a plurality of cascode transistors. The cascode transistors included in the cascode stage 120 may have a different polarity from the transistors of the input stage 110. For example, when the transistors of the input stage 110 are implemented as PMOS (P-type Metal Oxide Semiconductor) transistors, the cascode transistors may be implemented as NMOS (N-type Metal Oxide Semiconductor) transistors. As another example, when the transistors of the input stage 110 are implemented as NMOS transistors, the cascode transistors may be implemented as PMOS transistors.

According to embodiments, the cascode stage 120 may be formed in a cross-coupled structure where the gate of a cascode transistor is connected to the opposite output node. Here, the cross-coupled structure is a method configured such that the gate of one cascode transistor directly references the output voltage of the opposite node, and may be implemented in the form of dynamic feedback in which a change in the voltage of the output node is reflected in the operation of the cascode transistor. According to such a configuration, the effective input impedance of the cascode transistor may be reduced, and gain loss due to current division may be effectively reduced. However, the scope of the present disclosure is not limited to this, and in embodiments, the gate of the cascode transistor may be connected to a fixed bias voltage.

The output stage 130 may receive the AMPLIFIED SIGNAL transmitted from the cascode stage 120 and generate an OUTPUT SIGNAL based on the AMPLIFIED SIGNAL. The output stage 130 may, for example, include one or more load elements connected to the output side of the cascode stage 120. Such load elements contribute to the formation of the voltage level of the OUTPUT SIGNAL and may perform the role of adjusting the gain characteristics or frequency response characteristics of the circuit.

In some embodiments, the output stage 130 may include a resistor element connected between the output of the cascode stage 120 and a power supply voltage. In embodiments, the output stage 130 may also include a current source connected between the output of the cascode stage 120 and the power supply voltage. In embodiments, the output stage 130 may include a passive element (e.g., a capacitor, an inductor, etc.) connected between the outputs of the cascode stage 120 to perform the function of an integrator or a filter circuit.

The OUTPUT SIGNAL generated from the output stage 130 may be transmitted to an external circuit or a subsequent block of the memory device. In embodiments, the OUTPUT SIGNAL may be configured as a differential output signal pair, but is not limited thereto.

According to various embodiments of the present disclosure, the amplifier circuit 100 may include a cascode stage 120 to which a cross-coupled structure is applied. The cross-coupled structure means a method in which the gate of one cascode transistor is connected to the opposite output node, and through this, the voltage fluctuation of the output node can be designed to be directly reflected in the driving of the cascode transistor. Through this structure, the effective input impedance on the source side of the cascode transistor may be reduced, the gain loss due to current division may be suppressed, and a wide output swing and stable frequency response characteristics may be secured even in a limited power supply voltage environment. Accordingly, the amplifier circuit 100 according to the present disclosure may be effectively applied to various analog circuits, memory devices, and memory systems including memory devices that require high gain and high-speed operation.

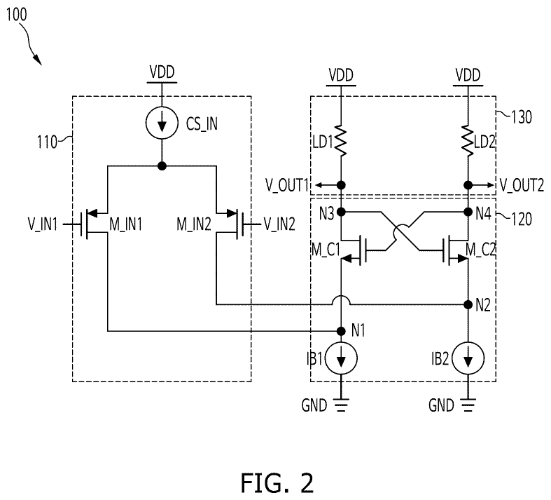

FIG. 2 is a circuit diagram for explaining an amplifier circuit according to some embodiments of the present disclosure.

Referring to FIG. 2, an amplifier circuit 100 may include an input stage 110, a cascode stage 120, and an output stage 130. However, the scope of the present disclosure is not limited to this, and the amplifier circuit 100 may further include additional components not illustrated in FIG. 2.

The input stage 110 may receive a first input signal V_IN1 and a second input signal V_IN2 from the outside, generate an internal current signal corresponding to these signals, and transmit the internal current signal to the cascode stage 120 through a first node N1 and a second node N2, respectively. That is, the input stage 110 may perform the role of converting an input signal into an internal current signal and supplying the internal current signal to a subsequent stage, as described in FIG. 1. In some embodiments, the first input signal V_IN1 and the second input signal V_IN2 may be a differential input signal pair in voltage form, but are not limited thereto. In addition, the first input signal V_IN1 and the second input signal V_IN2 may be provided from various circuit blocks such as a sensor circuit, a microcontroller, a control logic circuit of a memory device, an interface circuit, etc., depending on the implementation method.

The cascode stage 120 may receive the internal current signals provided from the first node N1 and the second node N2 and amplify them into an amplified signal. The cascode stage 120 may perform the role of stably amplifying the current in a high output impedance environment and then transmitting the amplified signal to the output stage 130 through a third node N3 and a fourth node N4, respectively. According to embodiments, the cascode stage 120 may be formed in a cross-coupled structure. The cross-coupled structure may be implemented as a structure in which the gate of a first cascode transistor M_C1 is connected to the opposite output node, the fourth node N4, and the gate of a second cascode transistor M_C2 is connected to the opposite output node, the third node N3.

The output stage 130 may receive the amplified signal transmitted from the cascode stage 120 and provide the received amplified signal to an external circuit or a subsequent circuit in the form of output signals V_OUT1, V_OUT2. The output stage 130 may output a first output signal V_OUT1 and a second output signal V_OUT2 through the third node N3 and the fourth node N4, respectively. In addition, the output stage 130 may include a load resistor or a current source for stably transmitting a signal at the end of the circuit, and these load elements may be connected to a power supply voltage VDD. Through the load elements included in the output stage 130, the amplified internal current signal may be converted into a voltage signal form and output through the output nodes. In some embodiments, the first output signal V_OUT1 and the second output signal V_OUT2 may be a differential output signal pair in voltage form. However, the present disclosure is not limited to this, and the first output signal V_OUT1 and the second output signal V_OUT2 may also be converted and output in various forms as needed.

The input stage 110 may include a first input transistor M_IN1 and a second input transistor M_IN2. In some embodiments, the first input transistor M_IN1 and the second input transistor M_IN2 may be PMOS transistors, but the scope of the present disclosure is not limited thereto. The first input transistor M_IN1 may have a source connected to an input current source CS_IN, a drain connected to the first node N1, and a first input signal V_IN1 applied to its gate. The second input transistor M_IN2 may have a source connected to the input current source CS_IN, a drain connected to the second node N2, and a second input signal V_IN2 applied to its gate.

The cascode stage 120 may include a first cascode transistor M_C1 and a second cascode transistor M_C2. In some embodiments, the first cascode transistor M_C1 and the second cascode transistor M_C2 may be NMOS transistors, but the scope of the present disclosure is not limited thereto. The first cascode transistor M_C1 may have a source connected to the first node N1, a drain connected to the third node N3, and a gate connected to the fourth node N4. The second cascode transistor M_C2 may have a source connected to the second node N2, a drain connected to the fourth node N4, and a gate connected to the third node N3.

In addition, the cascode stage 120 may include a first bias current source IB1 and a second bias current source IB2. The first bias current source IB1 may be connected between the first node N1 and a ground voltage GND, and the second bias current source IB2 may be connected between the second node N2 and the ground voltage GND.

The output stage 130 may include a first load element LD1 and a second load element LD2. The first load element LD1 may have one end connected to the power supply voltage VDD and the other end connected to the third node N3. The second load element LD2 may have one end connected to the power supply voltage VDD and the other end connected to the fourth node N4. As illustrated in FIG. 2, in some embodiments, the first load element LD1 and the second load element LD2 may be resistors. However, the present disclosure is not limited to this, and they may be replaced with transistors, active loads, or other current-driving elements according to the design purpose.

Meanwhile, according to various embodiments of the present disclosure, the cascode stage 120 may be implemented in a cross-coupled manner. That is, the gate of the first cascode transistor M_C1 is connected to the same node as the drain of the second cascode transistor M_C2 (i.e., the fourth node N4), and the gate of the second cascode transistor M_C2 is connected to the same node as the drain of the first cascode transistor M_C1 (i.e., the third node N3).

Through this cross-coupled structure, the gate voltage of each cascode transistor is affected by the voltage fluctuation of the opposite output node, and as a result, the effective input impedance generated at the source of the cascode transistor may be reduced. In addition, as the input impedance of the cascode stage 120 is reduced, the current that is generated in the input stage 110 and flows through the first node N1 and the second node N2 and branches to the first bias current source IB1 and the second bias current source IB2 may be reduced. Accordingly, the amount of current transmitted to the cascode stage 120 is relatively increased, so that the overall amplification gain loss is suppressed, and as a result, the gain of the amplifier circuit 100 may be effectively improved.

In addition, as more current is transmitted to the cascode stage 120, the current driving capability of the circuit is improved along with the reduction of the input impedance of the cascode transistor, so that the bandwidth characteristic may also be improved. In particular, since stable gain characteristics can be secured even in a high-frequency region, the amplifier circuit 100 according to the present disclosure can be advantageously applied even in application fields requiring high-speed operation.

In addition, since the cross-coupled structure is applied to the amplifier circuit 100, gain and bandwidth improvement can be achieved without additional complicated auxiliary circuits, so an advantage can also be provided in that the total area of the circuit can be effectively reduced or the performance per unit area can be maximized.

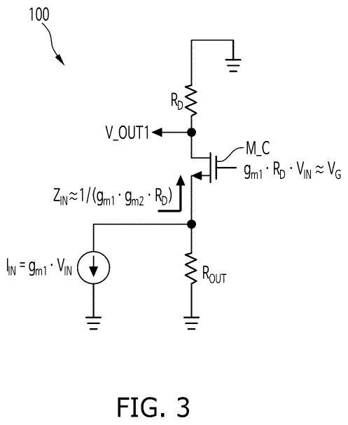

FIG. 3 is a diagram for explaining a small-signal model of the amplifier circuit illustrated in FIG. 2.

Referring to FIG. 3, an amplification path on one side having a cascode structure among the amplifier circuit 100 according to the present disclosure is illustrated in a small-signal model form.

First, an input transistor (for example, M_IN1 of FIG. 2) may receive an input signal and generate an internal current signal based on the received input signal. Equation 1 below represents the internal current signal generated by the input transistor.

I_{IN}=gₘ₁×V_{IN} [Equation 1]

Here, I_{IN} represents the internal current signal, gₘ₁ represents the transconductance of the input transistor, and V_{IN} represents the input voltage. V_{IN} may correspond to the small-signal component of the input signal (for example, V_IN1 of FIG. 2) applied to the gate of the input transistor.

At this time, the generated internal current signal may be transmitted to the source node of a cascode transistor M_C. At the source node, a part of the internal current signal may be branched in the direction of the ground voltage, and the rest may be transmitted to the source of the cascode transistor M_C.

The current distribution may be made based on the parallel impedance connected to the source node of the cascode transistor M_C. That is, the internal current signal I_{IN} may be branched as in Equation 2 below, based on the input impedance Z_{IN} of the cascode transistor M_C and the impedance R_{OUT} formed by a bias current source (for example, IB1 of FIG. 2).

$${I}_{M C} = {I}_{IN} \times \frac{{R}_{O U T}}{{R}_{O U T} + {Z}_{IN}} \qquad [ Equation 2 ]$$

Here, I_{MC} represents the current branching to the source of the cascode transistor M_C, Z_{IN} represents the effective input impedance on the source side of the cascode transistor M_C, and R_{OUT} represents the equivalent impedance formed by the bias current source connected to the source node of the cascode transistor M_C. Therefore, of the total current that has reached the source node, an amount of current determined by Equation 2 above may be transmitted through the cascode transistor M_C in the drain direction.

In an ideal case, the bias current source connected to the source node of the cascode transistor M_C may provide a very high impedance R_{OUT}. In such a case, most of the internal current signal I_{IN} may be transmitted to the source of the cascode transistor M_C without branching. However, in an actual circuit, since the impedance R_{OUT} formed by the bias current source has a finite value, a part of the internal current signal is branched in the ground direction, and due to this, the current injected into the cascode transistor M_C may be reduced.

According to various embodiments of the present disclosure, a cascode transistor M_C included in the cascode stage may be formed in a cross-coupled structure. In this structure, the gate of the cascode transistor M_C may be connected to the opposite output node. Therefore, the voltage applied to the gate of the cascode transistor M_C may be approximated as in Equation 3 below.

V_{G}≈gₘ₁×R_{D}×V_{IN} [Equation 3]

Here, V_{G} represents the voltage applied to the gate of the cascode transistor M_C, and R_{D} is an equivalent resistance corresponding to a load element, which may correspond to, for example, the first load element LD1 of FIG. 2.

Therefore, the effective input impedance formed by the voltage difference between the source and gate of the cascode transistor M_C may be approximated as in Equation 4 below.

$${Z}_{IN} \approx \frac{1}{{g}_{m 1} \times {g}_{m 2} \times {R}_{D}} \qquad [ Equation 4 ]$$

Here, gₘ₂ represents the transconductance of the cascode transistor M_C. This effective input impedance Z_{IN} may be approximated to a lower value than the input impedance that appears in a general cascode structure based on a bias voltage. Consequently, according to the current distribution ratio described in Equation 2 above, more current can be injected through the cascode transistor M_C, which can lead to an improvement in the output voltage and an improvement in the overall amplification gain of the amplifier circuit 100.

Specifically, the output voltage output from the amplifier circuit 100 and the total amplification gain Av may be approximated as in Equation 5 and Equation 6 below, respectively.

$${V}_{OUT 1} \approx - {I}_{M C} \times {R}_{D} = - {g}_{m 1} \times \frac{{R}_{O U T}}{{R}_{O U T} + {Z}_{IN}} \times {R}_{D} \times {V}_{IN} \qquad [ Equation 5 ]$$

$${A}_{V} = \frac{{V}_{O U T 1}}{{V}_{IN}} \approx - {g}_{m 1} \times \frac{{R}_{O U T}}{{R}_{O U T} + {Z}_{IN}} \times {R}_{D} \qquad [ Equation 6 ]$$

Here, Av represents the total amplification gain of the amplifier circuit 100. In addition, the minus sign represents a phase inversion between the input signal and the output voltage.

That is, in the amplifier circuit 100 according to the present disclosure, by reducing the input impedance Z_{IN} of the cascode transistor M_C through the cross-coupled structure, the current transmitted to the output stage is increased, and accordingly, the output voltage and the total amplification gain Av can be effectively improved. In addition, through the cross-coupled structure, not only is the gain improved, but also the frequency range in which the gain of the circuit is maintained is widened, so an effect of improving the bandwidth can be provided.

As such, by the cascode structure based on cross-coupling according to the present disclosure, the effective input impedance of the cascode stage is reduced without additional circuit blocks or complex design, so that the gain and bandwidth characteristics of the amplifier circuit can be simultaneously improved.

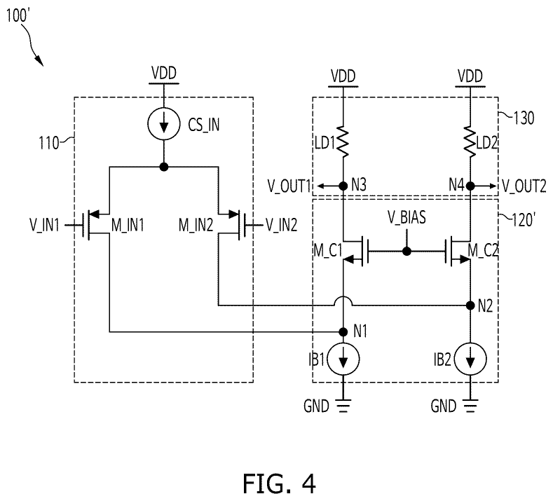

FIG. 4 is a circuit diagram for explaining an amplifier circuit according to some embodiments of the present disclosure.

Referring to FIG. 4, an amplifier circuit 100′ may include an input stage 110, a cascode stage 120′, and an output stage 130. The amplifier circuit 100′ illustrated in FIG. 4 may correspond to a comparative example of the amplifier circuit 100 illustrated in FIG. 2. Hereinafter, descriptions overlapping with the detailed description of FIG. 2 are omitted or briefly described.

The cascode stage 120′ may receive the internal current signals provided through the first node N1 and the second node N2, amplify them, and transmit them to the output stage 130 through the third node N3 and the fourth node N4. The cascode stage 120′ may include a first cascode transistor M_C1 and a second cascode transistor M_C2. The first cascode transistor M_C1 may have a source connected to the first node N1, a drain connected to the third node N3, and a gate connected to a bias voltage V_BIAS. The second cascode transistor M_C2 may have a source connected to the second node N2, a drain connected to the fourth node N4, and a gate connected to the bias voltage V_BIAS.

That is, instead of the cross-coupled connection structure as in the amplifier circuit 100 of FIG. 2, in the amplifier circuit 100′ of FIG. 4, the cascode stage 120′ may be implemented with a structure in which a fixed bias voltage is commonly applied to the gates of the first cascode transistor M_C1 and the second cascode transistor M_C2.

Such a structure has the advantage that the gate voltage of the cascode transistor can be statically set using the bias voltage V_BIAS supplied from the outside. However, since the gate of the cascode transistor is not connected to the opposite output node, the voltage fluctuation of the output node is not reflected in the gate voltage, and accordingly, the effective input impedance of the cascode stage 120′ can be maintained relatively high. As a result, a part of the internal current signal generated in the input stage 110 may be branched more to the first bias current source IB1 and the second bias current source IB2, which may cause a loss in the overall amplification gain of the amplifier circuit 100′.

Meanwhile, in the amplifier circuit 100 illustrated in FIG. 2, the gate voltage of the cascode transistor can be dynamically adjusted according to the voltage of the opposite output node through the cross-coupled structure. According to this configuration, the gate voltage can be automatically set even without a separate bias voltage supply circuit, so the amplifier circuit 100 can be simply implemented, and the area and power consumption can be effectively reduced. In addition, as the effective input impedance of the cascode stage is reduced, the loss due to current division is suppressed, so that the amplification gain and bandwidth characteristics can be effectively improved.

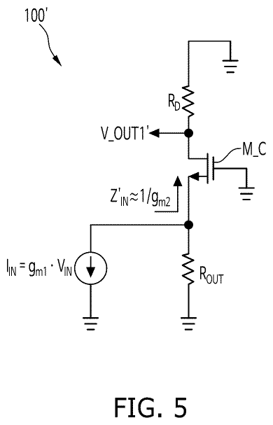

FIG. 5 is a diagram for explaining a small-signal model of the amplifier circuit illustrated in FIG. 4.

Referring to FIG. 5, an amplification path on one side having a cascode structure among an amplifier circuit 100′ is illustrated in a small-signal model form. The amplifier circuit 100′ illustrated in FIG. 5 may correspond to a comparative example of the amplifier circuit 100 illustrated in FIG. 3. Hereinafter, descriptions overlapping with the detailed description of FIG. 3 are omitted or briefly described.

According to the amplifier circuit 100′ illustrated in FIG. 4, a cascode transistor M_C included in the cascode stage may be formed in a structure driven by a fixed bias voltage (for example, V_BIAS of FIG. 4). In this structure, the gate of the cascode transistor M_C may be connected to a constant bias voltage rather than the opposite output node, and due to this, a constant voltage may be applied to the gate of the cascode transistor M_C.

Therefore, the effective input impedance formed by the voltage difference between the source and gate of the cascode transistor M_C may be approximated as in Equation 7 below.

$${Z}_{IN}^{′} = \frac{1}{{g}_{m 2}} \qquad [ Equation 7 ]$$

When compared with the effective input impedance Z_{IN} derived from the amplifier circuit 100 illustrated in FIG. 3, the effective input impedance Z′_{IN} derived from the amplifier circuit 100′ illustrated in FIG. 5 can be maintained at a relatively larger value.

As this input impedance Z′_{IN} increases, the current transmitted from the source node to the cascode transistor M_C may decrease. Specifically, the current transmitted from the source node to the cascode transistor M_C can be expressed by Equation 8 below.

$${I}_{M C}^{′} = {I}_{IN} \times \frac{{R}_{O U T}}{{R}_{O U T} + {Z}_{IN}^{′}} \qquad [ Equation 8 ]$$

Therefore, the output voltage V__{OUT1′} and the total amplification gain A′_{V} output from the amplifier circuit 100′ may be approximated as in Equation 9 and Equation 10 below, respectively.

$${V}_{O U T 1}^{′} \approx - {I}_{M C}^{′} \times {R}_{D} = - {g}_{m 1} \times \frac{{R}_{O U T}}{{R}_{O U T} + {Z}_{IN}^{′}} \times {R}_{D} \times {V}_{IN} \qquad [ Equation 9 ]$$

$${A}_{V}^{′} = \frac{{V}_{O U T 1}^{′}}{{V}_{IN}} \approx - {g}_{m 1} \times \frac{{R}_{O U T}}{{R}_{O U T} + {Z}_{IN}^{′}} \times {R}_{D} \qquad [ Equation 10 ]$$

That is, in the bias voltage-based structure according to the amplifier circuit 100′ of FIG. 5, the input impedance Z′_{IN} of the cascode transistor M_C may have a relatively large value compared to the cross-coupled structure according to the amplifier circuit 100 of FIG. 3. Due to this, the current transmitted from the source node of the cascode transistor M_C to the cascode transistor M_C is reduced, and as a result, the output voltage V__{OUT1′} and the total amplification gain A′_{V} may be reduced. In addition, as the current transmitted through the cascode transistor M_C is reduced, the current driving capability of the output node is limited, and the high-frequency response characteristic may also be relatively degraded.

Therefore, the amplifier circuit 100 of FIG. 3 according to the present disclosure can provide more improved gain and bandwidth characteristics compared to the amplifier circuit 100′ of FIG. 5, and can be effectively applied to various application circuits that require high-speed and high-gain characteristics.

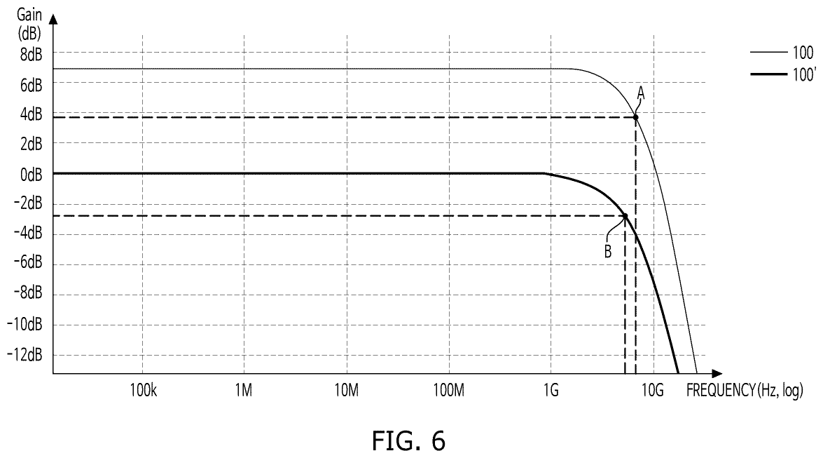

FIG. 6 is a graph comparing the gain by frequency between the amplifier circuit illustrated in FIGS. 2 and 3 and the amplifier circuit illustrated in FIGS. 4 and 5.

In the graph illustrated in FIG. 6, the horizontal axis (X-axis) represents frequency (Frequency, Hz, log scale), and the vertical axis (Y-axis) represents gain (Gain, dB). On the graph, the thin solid line corresponds to the amplifier circuit 100 illustrated in FIGS. 2 and 3, and the thick solid line corresponds to the amplifier circuit 100′ illustrated in FIGS. 4 and 5.

Referring to FIG. 6, according to the amplifier circuit 100 of the present disclosure, a higher gain can be maintained over the entire frequency range compared to the comparative example amplifier circuit 100′. In particular, a high gain is maintained even in the high-frequency region, so that wider bandwidth characteristics can be secured.

Specifically, according to the amplifier circuit 100 of the present disclosure, a gain of about 6.9 dB can be provided, and the frequency at point A, where the gain is reduced by 3 dB, is shown to be about 6.16 GHz. On the other hand, according to the comparative example amplifier circuit 100′, a gain of about 0 dB can be provided, and the frequency at point B, where the gain is reduced by 3 dB, is shown to be about 5.37 GHz.

That is, according to the amplifier circuit 100 of the present disclosure, not only can a higher initial gain be provided compared to the comparative example amplifier circuit 100′, but also the frequency range at which the gain begins to decrease is expanded, so that a wide bandwidth can be secured. This characteristic can be understood as a result of the effective input impedance of the cascode transistor being reduced and the output current driving capability being improved by applying the cross-coupled structure to the cascode stage.

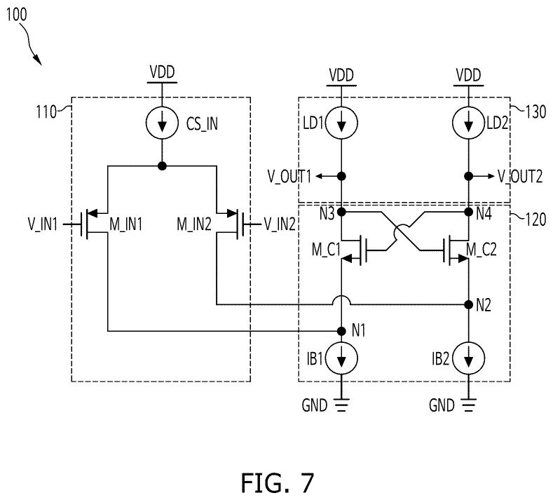

FIG. 7 is a diagram for explaining an amplifier circuit according to some embodiments of the present disclosure.

Hereinafter, descriptions overlapping with the above-mentioned descriptions are omitted or briefly described.

Referring to FIG. 7, an amplifier circuit 100 may include an input stage 110, a cascode stage 120, and an output stage 130.

In the embodiments illustrated in FIG. 7, a first load element LD1 and a second load element LD2 connected to the output stage 130 may each be implemented as a current source.

Specifically, the first load element LD1 may have one end connected to a power supply voltage VDD and the other end connected to a third node N3. The second load element LD2 may have one end connected to the power supply voltage VDD and the other end connected to a fourth node N4.

Here, the first load element LD1 and the second load element LD2 are not resistor elements having a fixed resistance value, but may be configured as current sources that supply a set current.

According to such a configuration, the output stage 130 can stably output the amplified signal while maintaining a constant current, without depending on the voltage drop caused by the load element. In particular, by applying a current source load, the output impedance is increased, and accordingly, the gain of the amplifier circuit 100 can be improved.

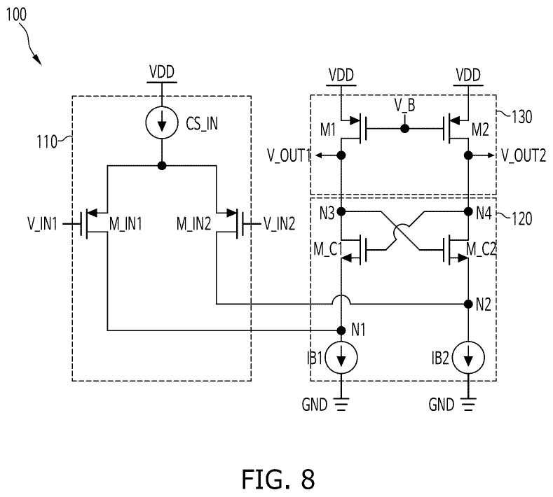

FIG. 8 is a diagram for explaining an amplifier circuit according to some embodiments of the present disclosure.

Hereinafter, descriptions overlapping with the above-mentioned descriptions are omitted or briefly described.

Referring to FIG. 8, an amplifier circuit 100 may include an input stage 110, a cascode stage 120, and an output stage 130. However, the scope of the present disclosure is not limited to this, and the amplifier circuit 100 may further include additional components not illustrated in FIG. 8.

In the embodiments illustrated in FIG. 8, the load element included in the output stage 130 may include a first transistor M1 and a second transistor M2.

Specifically, the first transistor M1 may have one end connected to a power supply voltage VDD, the other end connected to a third node N3, and a gate connected to a bias voltage V_B. The second transistor M2 may have one end connected to the power supply voltage VDD, the other end connected to a fourth node N4, and a gate connected to the bias voltage V_B.

In some embodiments, each of the first transistor M1 and the second transistor M2 may be a PMOS transistor, but the scope of the present disclosure is not limited thereto.

According to this configuration, the load element of the output stage 130 can be configured as a transistor to which a bias voltage V_B is applied, rather than a simple resistor element or a current source. Accordingly, the output impedance of the output stage 130 can be more effectively increased, and due to this, the overall gain of the amplifier circuit 100 can be improved.

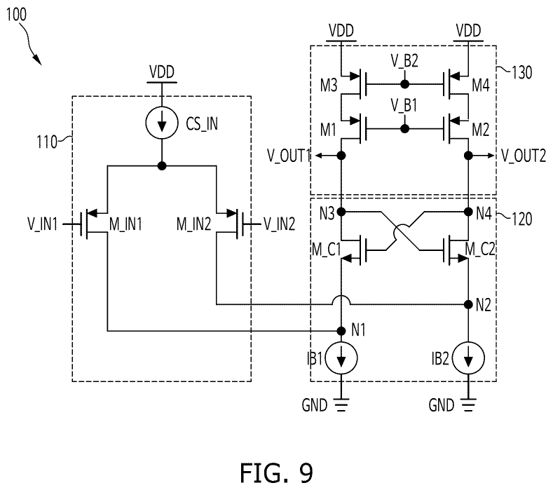

FIG. 9 is a diagram for explaining an amplifier circuit according to some embodiments of the present disclosure.

Hereinafter, descriptions overlapping with the above-mentioned descriptions are omitted or briefly described.

Referring to FIG. 9, an amplifier circuit 100 may include an input stage 110, a cascode stage 120, and an output stage 130. However, the scope of the present disclosure is not limited to this, and the amplifier circuit 100 may further include additional components not illustrated in FIG. 9.

In the embodiments illustrated in FIG. 9, the load element included in the output stage 130 may include a first transistor M1, a second transistor M2, a third transistor M3, and a fourth transistor M4. The first transistor M1 and the third transistor M3 may be connected in series, and the second transistor M2 and the fourth transistor M4 may be connected in series.

Specifically, the first transistor M1 may have one end connected to the drain of the third transistor M3, the other end connected to a third node N3, and a gate connected to a first bias voltage V_B1. The second transistor M2 may have one end connected to the drain of the fourth transistor M4, the other end connected to a fourth node N4, and a gate connected to the first bias voltage V_B1. In addition, the third transistor M3 may have one end connected to a power supply voltage VDD, the other end connected to the source of the first transistor M1, and a gate connected to a second bias voltage V_B2. The fourth transistor M4 may have one end connected to the power supply voltage VDD, the other end connected to the source of the second transistor M2, and a gate connected to the second bias voltage V_B2.

In some embodiments, each of the first to fourth transistors M1, M2, M3, M4 may be a PMOS transistor, but the scope of the present disclosure is not limited thereto. In addition, the first bias voltage V_B1 may be set differently from the second bias voltage V_B2, but the scope of the present disclosure is not limited thereto.

According to this configuration, the load element of the output stage 130 can be formed in a multi-stage connected transistor structure, that is, a cascode method. Through this, the output impedance of the output stage 130 can be more effectively increased, and due to this, the overall gain of the amplifier circuit 100 can be improved.

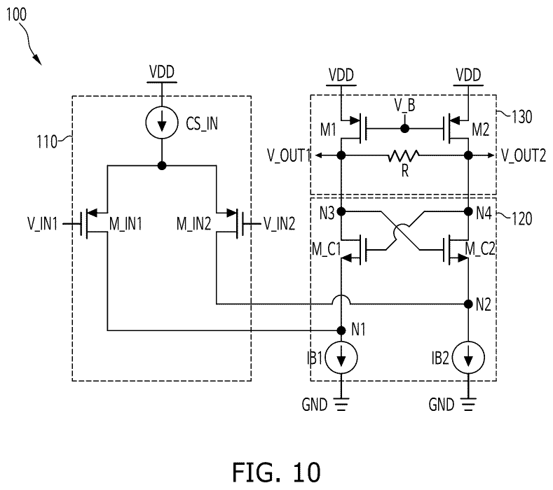

FIG. 10 is a diagram for explaining an amplifier circuit according to some embodiments of the present disclosure.

Hereinafter, descriptions overlapping with the above-mentioned descriptions are omitted or briefly described.

Referring to FIG. 10, an amplifier circuit 100 may include an input stage 110, a cascode stage 120, and an output stage 130. However, the scope of the present disclosure is not limited to this, and the amplifier circuit 100 may further include additional components not illustrated in FIG. 10.

In the embodiments illustrated in FIG. 10, the load element included in the output stage 130 includes a first transistor M1 and a second transistor M2, and a resistor element R may be additionally connected between the first transistor M1 and the second transistor M2. Specifically, the first transistor M1 may have one end connected to a power supply voltage VDD, the other end connected to a third node N3, and a gate connected to a bias voltage V_B. The second transistor M2 may have one end connected to the power supply voltage VDD, the other end connected to a fourth node N4, and a gate connected to the bias voltage V_B. In addition, the resistor element R may be connected between the node where a first output signal V_OUT1 is output (i.e., the third node N3) and the node where a second output signal V_OUT2 is output (i.e., the fourth node N4).

In some embodiments, the first transistor M1 and the second transistor M2 may be PMOS transistors, and the resistor element R may be a fixed resistor or a variable resistor, but the scope of the present disclosure is not limited thereto.

According to this configuration, even in a DC stable state, that is, a state where there is no data fluctuation in the output signal from the output stage 130, the common mode voltage levels of the third node N3 and the fourth node N4 can be effectively adjusted through the resistor element R. Accordingly, the DC voltage level of the output node is effectively adjusted, whereby the interface characteristics with a subsequent circuit can be improved.

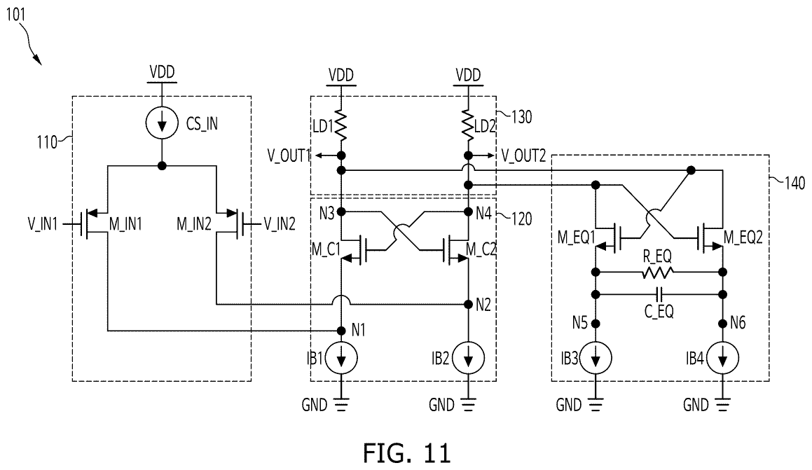

FIG. 11 is a diagram for explaining an amplifier circuit according to some embodiments of the present disclosure.

Hereinafter, descriptions overlapping with the above-mentioned descriptions are omitted or briefly described.

Referring to FIG. 11, an amplifier circuit 101 may include an input stage 110, a cascode stage 120, an output stage 130, and an equalization circuit 140. However, the scope of the present disclosure is not limited to this, and the amplifier circuit 101 may further include additional components not illustrated in FIG. 11.

The equalization circuit 140 may be configured to receive the output signals V_OUT1, V_OUT2 provided from the output stage 130, compensate for the imbalance in the frequency response that may be caused by channel loss, and improve signal distortion due to loss on the transmission path.

The equalization circuit 140 may include a first equalization transistor M_EQ1, a second equalization transistor M_EQ2, a resistor element R_EQ, and a capacitor C_EQ.

In some embodiments, the first equalization transistor M_EQ1 and the second equalization transistor M_EQ2 may be NMOS transistors, but the scope of the present disclosure is not limited thereto. In some embodiments, the first equalization transistor M_EQ1 and the second equalization transistor M_EQ2 may be PMOS transistors.

The first equalization transistor M_EQ1 may have a source connected to a fifth node N5, a drain connected to the fourth node N4 of the output stage 130, and a gate connected to the third node N3 of the output stage 130. The second equalization transistor M_EQ2 may have a source connected to a sixth node N6, a drain connected to the third node N3 of the output stage 130, and a gate connected to the fourth node N4 of the output stage 130.

In addition, the resistor element R_EQ and the capacitor C_EQ may each be connected in parallel between the fifth node N5 and the sixth node N6.

In embodiments, one end of the resistor element R_EQ is disposed between the source of the first equalization transistor M_EQ1 and one end of the capacitor C_EQ, and the other end of the resistor element R_EQ may be disposed between the source of the second equalization transistor M_EQ2 and the other end of the capacitor C_EQ. In addition, one end of the capacitor C_EQ may be disposed between one end of the resistor element R_EQ and a third bias current source IB3, and the other end of the capacitor C_EQ may be disposed between the other end of the resistor element R_EQ and a fourth bias current source IB4.

In embodiments, unlike what is illustrated in FIG. 11, one end of the capacitor C_EQ is disposed between the source of the first equalization transistor M_EQ1 and one end of the resistor element R_EQ, and the other end of the capacitor C_EQ may be disposed between the source of the second equalization transistor M_EQ2 and the other end of the resistor element R_EQ. In addition, one end of the resistor element R_EQ may be disposed between one end of the capacitor C_EQ and a third bias current source IB3, and the other end of the resistor element R_EQ may be disposed between the other end of the capacitor C_EQ and a fourth bias current source IB4.

A third bias current source IB3 may have one end connected to the fifth node N5 and the other end connected to a ground voltage GND. A fourth bias current source IB4 may have one end connected to the sixth node N6 and the other end connected to the ground voltage GND.

According to this embodiment, the internal current signal generated in the input stage 110 may be converted into output signals V_OUT1, V_OUT2 via the cascode stage 120 and the output stage 130. The loss of high-frequency components of the output signals V_OUT1, V_OUT2 is compensated through the equalization circuit 140, and a stable voltage level can be maintained for low-frequency components through the resistor element R_EQ. Accordingly, high-frequency loss on the transmission path is compensated, and signal distortion can be reduced over the entire frequency band.

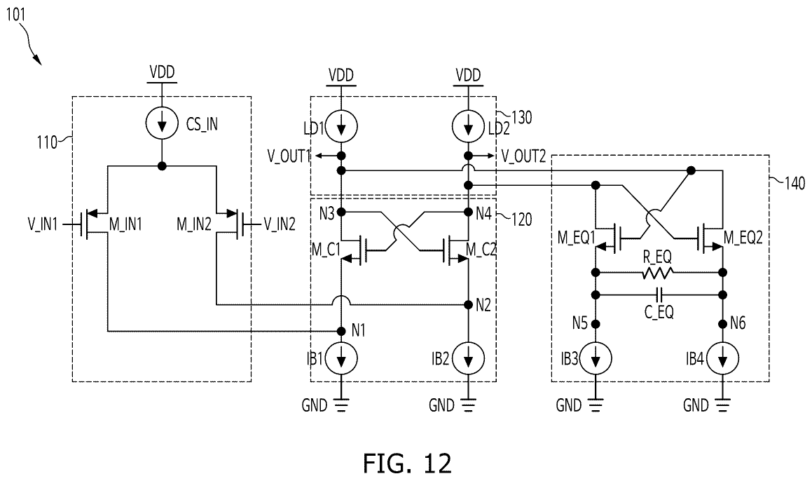

FIG. 12 is a diagram for explaining an amplifier circuit according to some embodiments of the present disclosure.

Hereinafter, descriptions overlapping with the above-mentioned descriptions are omitted or briefly described.

Referring to FIG. 12, an amplifier circuit 101 may include an input stage 110, a cascode stage 120, an output stage 130, and an equalization circuit 140.

In the embodiments illustrated in FIG. 12, when compared to the amplifier circuit 101 illustrated in FIG. 11, a first load element LD1 and a second load element LD2 connected to the output stage 130 may each be implemented as a current source. Here, the first load element LD1 and the second load element LD2 are not resistor elements having a fixed resistance value, but may be configured as current sources that supply a set current.

According to such a configuration, the output stage 130 can stably output the amplified signal while maintaining a constant current, without depending on the voltage drop caused by the load element. In particular, by applying a current source load, the output impedance is increased, and accordingly, the gain of the amplifier circuit 101 can be improved.

In addition, in the embodiments illustrated in FIG. 12, when compared to the amplifier circuit 100 illustrated in FIG. 7, an equalization circuit 140 connected to the output stage 130 may be further included.

The equalization circuit 140 may be configured to receive the output signals V_OUT1, V_OUT2 provided from the output stage 130, compensate for the imbalance in the frequency response that may be caused by channel loss, and improve signal distortion due to loss on the transmission path.

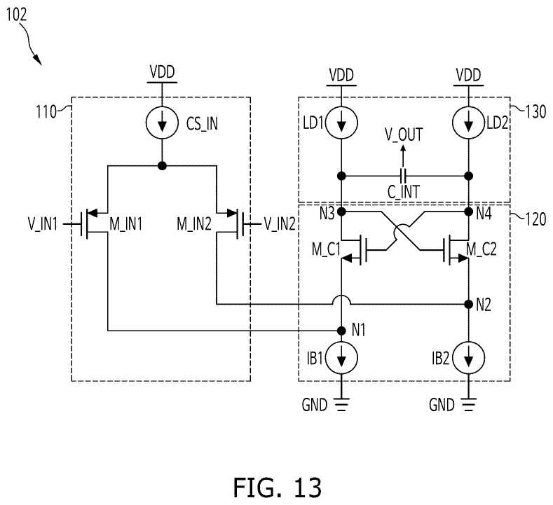

FIG. 13 is a diagram for explaining an amplifier circuit according to some embodiments of the present disclosure.

Hereinafter, descriptions overlapping with the above-mentioned descriptions are omitted or briefly described.

Referring to FIG. 13, an amplifier circuit 102 may include an input stage 110, a cascode stage 120, and an output stage 130. However, the scope of the present disclosure is not limited to this, and the amplifier circuit 102 may further include additional components not illustrated in FIG. 13.

The output stage 130 may include a first load element LD1, a second load element LD2, and a capacitor C_INT.

The capacitor C_INT may be connected between a third node N3 and a fourth node N4. Specifically, one end of the capacitor C_INT is connected between the drain of a first cascode transistor M_C1 and the first load element LD1, and the other end of the capacitor C_INT may be connected between the drain of a second cascode transistor M_C2 and the second load element LD2.

According to this embodiment, the capacitor C_INT can generate an output signal V_OUT based on the current flowing between the third node N3 and the fourth node N4. That is, the internal current signal generated in the input stage 110 by the input signals V_IN1, V_IN2 is transmitted to the third node N3 and the fourth node N4 via the cascode stage 120, and the transmitted current signal is charged in the capacitor C_INT and can be converted into a voltage signal over time. Accordingly, the result of current integration corresponding to the input signal can be output in voltage form at both ends of the capacitor C_INT.

Therefore, in the embodiments according to FIG. 13, the amplifier circuit 102 can operate as an integrator structure that integrates the current generated by the input signal in the capacitor C_INT, and through this, a voltage output corresponding to the temporal change of the input signal can be obtained. In addition, by applying a cross-coupled structure to the cascode stage 120, the input impedance of the cascode transistor is reduced, and current loss is suppressed, so that the accuracy and stability of the integration operation can be improved.

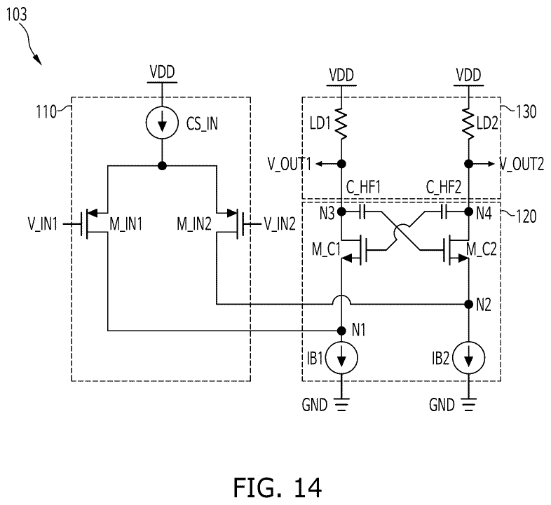

FIG. 14 is a diagram for explaining an amplifier circuit according to some embodiments of the present disclosure.

Hereinafter, descriptions overlapping with the above-mentioned descriptions are omitted or briefly described.

Referring to FIG. 14, an amplifier circuit 103 may include an input stage 110, a cascode stage 120, and an output stage 130. However, the scope of the present disclosure is not limited to this, and the amplifier circuit 103 may further include additional components not illustrated in FIG. 14.

In the embodiments illustrated in FIG. 14, the cascode stage 120 may include a first cascode transistor M_C1, a second cascode transistor M_C2, a first bias current source IB1, a second bias current source IB2, a first capacitor C_HF1, and a second capacitor C_HF2.

Specifically, the first capacitor C_HF1 is connected between the gate of the second cascode transistor M_C2 and a third node N3, and the second capacitor C_HF2 may be connected between the gate of the first cascode transistor M_C1 and a fourth node N4.

That is, the signal fed back from the drain of the second cascode transistor M_C2 to the gate of the first cascode transistor M_C1 passes through the second capacitor C_HF2, and the signal fed back from the drain of the first cascode transistor M_C1 to the gate of the second cascode transistor M_C2 may pass through the first capacitor C_HF1.

According to this configuration, the amplifier circuit 103 according to this embodiment can perform a high-pass filter function that passes high-frequency components and blocks low-frequency components, as the first capacitor C_HF1 and the second capacitor C_HF2 are placed in the feedback path. As a result, the amplifier circuit 103 can perform an operation of emphasizing high-frequency components and suppressing low-frequency components among input signals, and through this, it can be effectively applied to application fields requiring high-speed response characteristics. In addition, due to the cross-coupled structure applied to the cascode stage 120, current loss is suppressed even in the high-frequency region, and the output impedance characteristic is stabilized, so that the amplification characteristic can be maintained even after high-pass filtering.

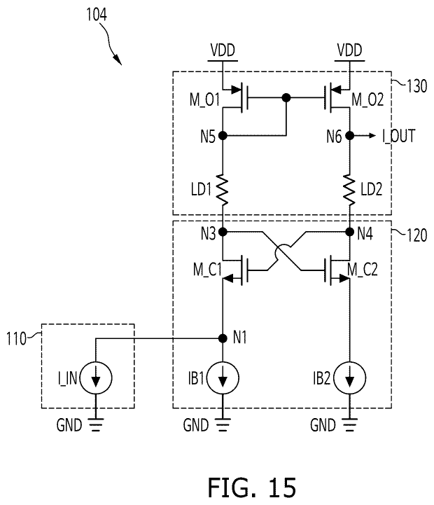

FIG. 15 is a diagram for explaining an amplifier circuit according to some embodiments of the present disclosure.

Hereinafter, descriptions overlapping with the above-mentioned descriptions are omitted or briefly described.

Referring to FIG. 15, an amplifier circuit 104 may include an input stage 110, a cascode stage 120, and an output stage 130. However, the scope of the present disclosure is not limited to this, and the amplifier circuit 104 may further include additional components not illustrated in FIG. 15.

The input stage 110 may include an input current source I_IN configured to provide an input current signal. In FIG. 15, only the input current source I_IN is illustrated, but various types of input circuits or input elements for providing the input current signal may be additionally included.

In addition, although a structure in which current is input in one polarity direction is illustrated in FIG. 15, in embodiments, the input stage 110 may be connected across a first node N1 and a second node N2 to be implemented in a form that provides a differential input signal pair.

The cascode stage 120 may perform the role of receiving and amplifying the current signal provided from the input stage 110. The cascode stage 120 may include a first cascode transistor M_C1, a second cascode transistor M_C2, a first bias current source IB1, and a second bias current source IB2. In some embodiments, the first cascode transistor M_C1 and the second cascode transistor M_C2 may be connected in a cross-coupled structure. Through this, the input impedance of the cascode stage 120 can be reduced, current loss can be suppressed, and current transfer efficiency and bandwidth characteristics can be improved.

The output stage 130 may receive the current signal received from the cascode stage 120 and provide it to the outside in the form of an output signal I_OUT.

The output stage 130 may include a first output transistor M_O1, a second output transistor M_O2, a first load element LD1, and a second load element LD2. Specifically, the first output transistor M_O1 has one end connected to a power supply voltage VDD, the other end connected to a fifth node N5 between the first output transistor M_O1 and the first load element LD1, and a gate connected to the fifth node N5 and the gate of the second output transistor M_O2. The second output transistor M_O2 has one end connected to the power supply voltage VDD, the other end connected to a sixth node N6 between the second output transistor M_O2 and the second load element LD2, and a gate connected to the fifth node N5 and the gate of the first output transistor M_O1. The output stage 130 may output an output signal I_OUT through the sixth node N6.

In some embodiments, each of the first output transistor M_O1 and the second output transistor M_O2 may be implemented as a PMOS transistor, but is not limited thereto.

In some embodiments, the first load element LD1 and the second load element LD2 may be implemented as resistors, but the present disclosure is not limited to this and they may also be implemented as current sources or other various load elements.

In the embodiments according to FIG. 15, the amplifier circuit 104 can perform a current conveyor function that transmits an input current signal to an output signal I_OUT without loss after receiving the input current signal. According to this configuration, the amplifier circuit 104 according to this embodiment can convert the input current signal into an output signal while minimizing loss, and in particular, due to the application of the cross-coupled structure, the current branching to the first bias current source IB1 is minimized, so that the current transfer efficiency can be maximized.

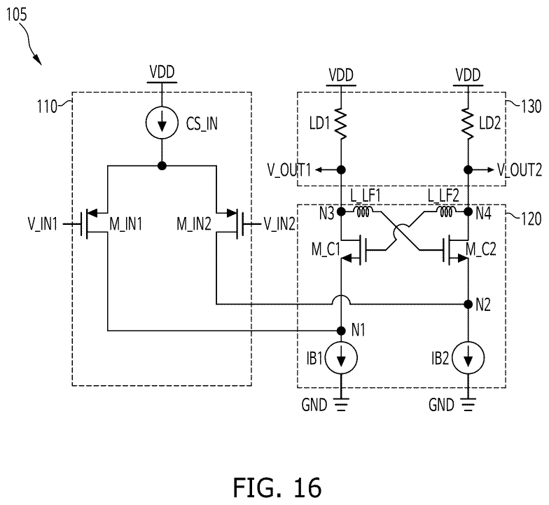

FIG. 16 is a diagram for explaining an amplifier circuit according to some embodiments of the present disclosure.

Hereinafter, descriptions overlapping with the above-mentioned descriptions are omitted or briefly described.

Referring to FIG. 16, an amplifier circuit 105 may include an input stage 110, a cascode stage 120, and an output stage 130. However, the scope of the present disclosure is not limited to this, and the amplifier circuit 105 may further include additional components not illustrated in FIG. 16.

In the embodiments illustrated in FIG. 16, the cascode stage 120 may include a first cascode transistor M_C1, a second cascode transistor M_C2, a first bias current source IB1, a second bias current source IB2, a first inductor L_LF1, and a second inductor L_LF2.

Specifically, the first inductor L_LF1 is connected between the gate of the second cascode transistor M_C2 and a third node N3, and the second inductor L_LF2 may be connected between the gate of the first cascode transistor M_C1 and a fourth node N4.

That is, the signal fed back from the drain of the second cascode transistor M_C2 to the gate of the first cascode transistor M_C1 passes through the second inductor L_LF2, and the signal fed back from the drain of the first cascode transistor M_C1 to the gate of the second cascode transistor M_C2 may pass through the first inductor L_LF1.

According to this configuration, the amplifier circuit 105 according to this embodiment can perform a low-pass filter function that passes low-frequency components and blocks high-frequency components, as the first inductor L_LF1 and the second inductor L_LF2 are placed in the feedback path.

As a result, the amplifier circuit 105 can perform an operation of emphasizing low-frequency components and suppressing high-frequency components among input signals, and through this, it can be effectively applied to application fields that require low-noise characteristics or processing of low-frequency band signals. In addition, due to the cross-coupled structure applied to the cascode stage 120, current loss is suppressed even in the low-frequency region, and the output impedance characteristic is stabilized, so that a high gain characteristic for low-frequency components can be stably maintained even after low-pass filtering.

Meanwhile, the embodiments according to FIGS. 2 and 7 to 16 illustrated in this specification can be applied not only alone, but also can be implemented by being combined in various ways with each other. For example, the configuration including the equalization circuit 140 illustrated in FIG. 11 is a configuration in which single-stage transistors M1, M2 are used as the load element of the output stage 130 as illustrated in FIG. 8, a configuration in which two-stage transistors M1, M2, M3, M4 are used as the load element of the output stage 130 as illustrated in FIG. 9, or a configuration in which the output stage 130 further includes a resistor element R as illustrated in FIG. 10, and can be implemented in combination with at least one of them. As such, the amplifier circuit according to the present disclosure can be implemented in an optimized form in response to various circuit conditions or design requirements by selectively combining or modifying the components illustrated in each embodiment. However, these various modifications and combinations can be made within a scope that does not depart from the technical spirit of the present disclosure.

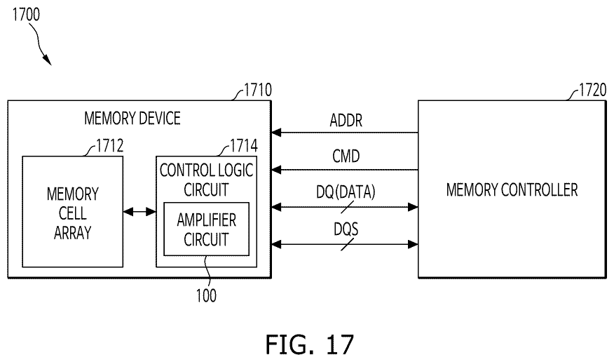

FIG. 17 is a block diagram for explaining a memory system according to some embodiments of the present disclosure.

Hereinafter, descriptions overlapping with the above-mentioned descriptions are omitted or briefly described.

Referring to FIG. 17, a memory system 1700 may include a memory device 1710 and a memory controller 1720.

The memory controller 1720 may perform an operation of writing DATA to the memory device 1710 or reading DATA stored in the memory device 1710. For example, the memory controller 1720 may generate a command CMD and an address ADDR for writing DATA to the memory device 1710 or reading DATA stored in the memory device 1710. In some embodiments, the memory controller 1720 may be at least one of a memory controller for controlling the memory device 1710, a system-on-chip (SoC) such as an application processor (AP), a central processing unit (CPU), a digital signal processor (DSP), and a graphics processing unit (GPU).

The memory device 1710 may store DATA received through a plurality of data lines DQ according to the control of the memory controller 1720 or transmit DATA stored in the memory device 1710 to the memory controller 1720 through the plurality of data lines DQ. The memory device 1710 may transmit data to the memory controller 1720 in synchronization with a data strobe signal provided through a data strobe line DQS. For example, between the memory device 1710 and the memory controller 1720, DATA may be transmitted and received through a plurality of data lines DQ and a data strobe line DQS.

In some embodiments, the memory device 1710 may include a non-volatile memory device and/or a volatile memory device.

For example, the memory device 1710 may include a flash memory device, and the flash memory device may be implemented as a 2D NAND memory array or a 3D NAND memory array (which may include a vertical or bonding-vertical structure).

As another example, the memory device 1710 may include at least one of various types of volatile or non-volatile memory devices such as DRAM (Dynamic RAM), SRAM (Static RAM), SDRAM (Synchronous DRAM), ROM (Read Only Memory), PROM (Programmable ROM), EPROM (Electrically Programmable ROM), EEPROM (Electrically Erasable and Programmable ROM), MRAM (Magnetic RAM), Spin-Transfer Torque MRAM, CBRAM (Conductive Bridging RAM), RRAM (Resistive RAM), PRAM (Phase-Change RAM), and FRAM (Ferroelectric RAM).

In some embodiments, the memory device 1710 may include a memory cell array 1712 and a control logic circuit 1714.

The memory cell array 1712 may be composed of a plurality of memory cells arranged in a matrix form, and the control logic circuit 1714 is configured to control the operation of the memory cell array 1712 and may include an amplifier circuit 100 for amplifying an input signal received from an external device. The amplifier circuit 100 included in the control logic circuit 1714 may be configured to amplify a data signal received from the memory controller 1720 to improve signal quality and support stable data processing even in a high-speed data transmission environment.

The amplifier circuit 100 according to the present disclosure may be implemented with a structure including an input stage, a cascode stage, and an output stage, and in particular, since the cascode stage is formed in a cross-coupled structure, the input impedance is reduced and current loss is suppressed, so that the gain characteristic and bandwidth characteristic of the amplifier can be effectively improved.

The amplifier circuit 100 according to the present disclosure is described in more detail with reference to the drawings illustrated in FIGS. 1 to 16.

According to embodiments of the present disclosure, the amplifier circuit 100 may be applied to stably amplify not only data signals but also various signals received from an external device, such as various types of control signals and address signals.

In addition, the amplifier circuit 100 according to the present disclosure may be applied not only to the control logic circuit 1714 but also to an interface circuit, a receiving circuit, or other various circuit blocks within the memory device 1710. For example, when the amplifier circuit 100 includes an equalization circuit (e.g., the equalization circuit 140 illustrated in FIG. 11), the amplifier circuit 100 may be applied to a receiving circuit to perform an equalization function that compensates for frequency response imbalance that may occur due to channel loss and improves signal distortion on the transmission path. Through this, the signal quality can be improved even during high-speed data transmission and reception between the memory device 1710 and the memory controller 1720.

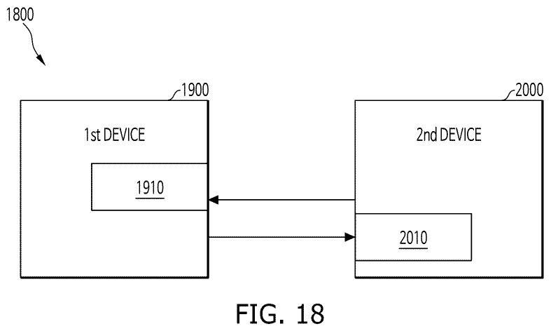

FIG. 18 is a block diagram illustrating an example of an electronic device provided with an amplifier circuit according to some embodiments of the present disclosure.

Referring to FIG. 18, a system 1800 may include a first electronic device 1900 and a second electronic device 2000. The first electronic device 1900 and the second electronic device 2000 may each be various information processing devices that transmit and receive data signals, electrical signals, analog signals, or digital signals, such as a signal receiver, a signal transmitter, an electronic module, an electronic circuit, or an Intellectual Property (IP) block.

The first electronic device 1900 and the second electronic device 2000 may each include an amplifier circuit 1910, 2010. The amplifier circuits 1910, 2010 may be the amplifier circuit described with reference to the embodiments illustrated in FIGS. 1 to 16. That is, the amplifier circuits 1910, 2010 may be configured to amplify a signal received from the first electronic device 1900 or the second electronic device 2000, remove noise, and stabilize signal quality even in a high-speed data transmission environment.

In particular, the amplifier circuits 1910, 2010 according to the present disclosure may have a structure including an input stage, a cascode stage having a cross-coupled structure, and an output stage. Through this, the input impedance is reduced and current loss is suppressed, so that the gain and bandwidth characteristics of the received signal can be effectively improved.

In some embodiments, a method of manufacturing an amplifier circuit may include providing an input stage configured to receive an input signal and generate an internal current signal, providing a cascode stage connected to the input stage and configured to amplify the internal current signal transmitted from the input stage into an amplified signal through a cascode structure, and providing an output stage configured to output an output signal based on the amplified signal transmitted from the cascode stage, wherein the cascode stage may include a first cascode transistor having one end connected to the input stage and another end connected to a first node, and a second cascode transistor having one end connected to the input stage and another end connected to a second node, and wherein the gate of the first cascode transistor is connected to the second node, and the gate of the second cascode transistor is connected to the first node.

In some embodiments, a method of manufacturing a memory device may include providing a memory cell array, and providing a control logic circuit configured to control the memory cell array and may include providing an amplifier circuit configured to amplify an input signal received from an external device, wherein the amplifier circuit may include a first input transistor having one end connected to an input current source, another end connected to a first node, and a first input signal applied to a gate thereof, a second input transistor having one end connected to the input current source, another end connected to a second node, and a second input signal applied to a gate thereof, a first bias current source having one end connected to the first node and another end connected to a ground voltage, a second bias current source having one end connected to the second node and another end connected to the ground voltage, a first cascode transistor having one end connected to the first node and another end connected to a third node, a second cascode transistor having one end connected to the second node and another end connected to a fourth node, a first load element having one end connected to a power supply voltage and another end connected to the third node, and a second load element having one end connected to the power supply voltage and another end connected to the fourth node, and wherein the gate of the first cascode transistor is connected to the fourth node, and the gate of the second cascode transistor is connected to the third node.

The above-described preferred embodiment of the present disclosure is disclosed for the purpose of illustration, and those skilled in the art of the present disclosure will be able to make various modifications, changes, and additions within the spirit and scope of the present disclosure, and such modifications, changes, and additions should be regarded as belonging to the scope of the patent claims.

A person of ordinary skill in the technical field to which the present disclosure belongs can make various substitutions, modifications, and changes within a scope that does not depart from the technical spirit of the present disclosure, and therefore, the present disclosure is not limited by the above-described embodiments and the attached drawings.

What is claimed is:

1. An amplifier circuit comprising:
an input stage configured to receive an input signal and generate an internal current signal;
a cascode stage connected to the input stage and configured to amplify the internal current signal transmitted from the input stage into an amplified signal through a cascode structure; and
an output stage configured to output an output signal based on the amplified signal transmitted from the cascode stage,
wherein the cascode stage comprises:
a first cascode transistor having one end connected to the input stage and another end connected to a first node; and
a second cascode transistor having one end connected to the input stage and another end connected to a second node, and
wherein the gate of the first cascode transistor is connected to the second node, and the gate of the second cascode transistor is connected to the first node.

2. The amplifier circuit as claimed in claim 1,
wherein:
a first output signal is output through the first node,
a second output signal is output through the second node, and
the gate of the first cascode transistor is directly connected to the second node, and the gate of the second cascode transistor is directly connected to the first node.

3. The amplifier circuit as claimed in claim 2,
wherein:
the input signal is a differential input signal pair, and
the first output signal and the second output signal are a differential output signal pair.

4. The amplifier circuit as claimed in claim 1,
wherein the input stage comprises:
a first input transistor having one end connected to an input current source, another end connected to the first cascode transistor, and a first input signal applied to a gate thereof, and
a second input transistor having one end connected to the input current source, another end connected to the second cascode transistor, and a second input signal applied to a gate thereof,
wherein the first input transistor and the second input transistor are PMOS transistors, and
the first cascode transistor and the second cascode transistor are NMOS transistors.

5. The amplifier circuit as claimed in claim 1,
further comprising an equalization circuit connected to the first node and the second node,
wherein the equalization circuit comprises:
a first equalization transistor having one end connected to the second node, another end connected to a third node, and a gate connected to the first node;
a second equalization transistor having one end connected to the first node, another end connected to a fourth node, and a gate connected to the second node;
a resistor connected between the third node and the fourth node;
a capacitor connected between the third node and the fourth node;
a first bias current source having one end connected to the third node and another end connected to a ground voltage; and
a second bias current source having one end connected to the fourth node and another end connected to the ground voltage.

6. The amplifier circuit as claimed in claim 1,
wherein the cascode stage further comprises:
a first capacitor connected between the gate of the second cascode transistor and the first node, and
a second capacitor connected between the gate of the first cascode transistor and the second node.

7. The amplifier circuit as claimed in claim 1,
wherein the cascode stage further comprises:
a first inductor connected between the gate of the second cascode transistor and the first node, and
a second inductor connected between the gate of the first cascode transistor and the second node.

8. The amplifier circuit as claimed in claim 1,
wherein the output stage comprises:
a first resistor having one end connected to a power supply voltage and another end connected to the first node; and
a second resistor having one end connected to the power supply voltage and another end connected to the second node.

9. The amplifier circuit as claimed in claim 8,
wherein the output stage further comprises:
a first output transistor connected between the first resistor and the power supply voltage; and
a second output transistor connected between the second resistor and the power supply voltage,
wherein:
one end of the first output transistor is connected to the power supply voltage, another end of the first output transistor is connected to a third node located between the first output transistor and the first resistor, and the gate of the first output transistor is connected to the third node,
one end of the second output transistor is connected to the power supply voltage, another end of the second output transistor is connected to a fourth node located between the second output transistor and the second resistor, and the gate of the second output transistor is connected to the third node, and
the output signal is output through the fourth node.

10. The amplifier circuit as claimed in claim 1,
wherein the output stage further comprises:
a capacitor connected between the first node and the second node and configured to generate the output signal based on a current flowing between the first node and the second node.

11. The amplifier circuit as claimed in claim 1,
wherein the output stage comprises:
a first bias current source having one end connected to a power supply voltage and another end connected to the first node; and
a second bias current source having one end connected to the power supply voltage and another end connected to the second node.

12. A memory device comprising:
a memory cell array; and
a control logic circuit configured to control the memory cell array and comprising an amplifier circuit configured to amplify an input signal received from an external device,
wherein the amplifier circuit comprises:
a first input transistor having one end connected to an input current source, another end connected to a first node, and a first input signal applied to a gate thereof,
a second input transistor having one end connected to the input current source, another end connected to a second node, and a second input signal applied to a gate thereof,
a first bias current source having one end connected to the first node and another end connected to a ground voltage;
a second bias current source having one end connected to the second node and another end connected to the ground voltage;
a first cascode transistor having one end connected to the first node and another end connected to a third node;
a second cascode transistor having one end connected to the second node and another end connected to a fourth node;
a first load element having one end connected to a power supply voltage and another end connected to the third node; and
a second load element having one end connected to the power supply voltage and another end connected to the fourth node, and
wherein the gate of the first cascode transistor is connected to the fourth node, and the gate of the second cascode transistor is connected to the third node.

13. The memory device as claimed in claim 12,
wherein:
a first output signal is output through the third node,
a second output signal is output through the fourth node, and
the gate of the first cascode transistor is directly connected to the fourth node, and the gate of the second cascode transistor is directly connected to the third node.

14. The memory device as claimed in claim 13,
wherein:
the first input signal and the second input signal are a differential input signal pair, and
the first output signal and the second output signal are a differential output signal pair.

15. The memory device as claimed in claim 12,
wherein:
the amplifier circuit further comprises an equalization circuit connected to the third node and the fourth node, and
the equalization circuit comprises:
a first equalization transistor having one end connected to the fourth node, another end connected to a fifth node, and a gate connected to the third node;
a second equalization transistor having one end connected to the third node, another end connected to a sixth node, and a gate connected to the fourth node;
a resistor connected between the fifth node and the sixth node;
a capacitor connected between the fifth node and the sixth node;
a third bias current source having one end connected to the fifth node and another end connected to the ground voltage; and
a fourth bias current source having one end connected to the sixth node and another end connected to the ground voltage.

16. The memory device as claimed in claim 12,
wherein the amplifier circuit further comprises a first capacitor connected between the gate of the second cascode transistor and the third node, and a second capacitor connected between the gate of the first cascode transistor and the fourth node.

17. The memory device as claimed in claim 12,
wherein the amplifier circuit further comprises a first inductor connected between the gate of the second cascode transistor and the third node, and a second inductor connected between the gate of the first cascode transistor and the fourth node.

18. The memory device as claimed in claim 12,
wherein the amplifier circuit further comprises:
a first output transistor connected between the first load element and the power supply voltage; and
a second output transistor connected between the second load element and the power supply voltage,
one end of the first output transistor is connected to the power supply voltage, another end of the first output transistor is connected to a fifth node located between the first output transistor and the first load element, and the gate of the first output transistor is connected to the fifth node,
one end of the second output transistor is connected to the power supply voltage, another end of the second output transistor is connected to a sixth node located between the second output transistor and the second load element, and the gate of the second output transistor is connected to the fifth node, and
the output signal is output through the sixth node.

19. The memory device as claimed in claim 12,
wherein the amplifier circuit further comprises a capacitor connected between the third node and the fourth node and configured to generate an output signal based on a current flowing between the third node and the fourth node.

20. An amplifier circuit comprising:
a first input transistor having one end connected to an input current source, another end connected to a first node, and a first input signal applied to a gate thereof,
a second input transistor having one end connected to the input current source, another end connected to a second node, and a second input signal applied to a gate thereof,
a first bias current source having one end connected to the first node and another end connected to a ground voltage;
a second bias current source having one end connected to the second node and another end connected to the ground voltage;
a first cascode transistor having one end connected to the first node and another end connected to a third node;
a second cascode transistor having one end connected to the second node and another end connected to a fourth node;
a first load element having one end connected to a power supply voltage and another end connected to the third node; and
a second load element having one end connected to the power supply voltage and another end connected to the fourth node,
wherein a first output signal is output through the third node,
a second output signal is output through the fourth node,
the gate of the first cascode transistor is directly connected to the fourth node, and the gate of the second cascode transistor is directly connected to the third node,
the first input signal and the second input signal are a differential input signal pair, and
the first output signal and the second output signal are a differential output signal pair.
